(19) United States
(12) Patent Application Publication
(10) Pub. No.: US 2026/0028747 A1
(43) Pub. Date: Jan. 29, 2026

(54) SYSTEMS AND METHODS FOR MODEL BASED LUMP PARAMETER ESTIMATION OF AXIAL GRADIENTS IN MELT AND CRYSTAL AT THE GROWING INTERFACE

(71) Applicant: GlobalWafers Co., Ltd., Hsinchu (TW)

(72) Inventor: Michael Neubert, Berlin (DE)

(21) Appl. No.: 19/281,130

(22) Filed: Jul. 25, 2025

Related U.S. Application Data
(60) Provisional application No. 63/675,534, filed on Jul. 25, 2024.

(51) Int. Cl. C30B 15/20; C30B 29/06

(52) U.S. Cl. CPC C30B 15/20; C30B 29/06

(57) ABSTRACT

A computer device includes at least one processor in communication with at least one memory device. The at least one processor is programmed to: a) receive data for simulating a process on the device; b) determine a plurality of gradient variables; c) determine a plurality of fit coefficients for the plurality of gradient variables; d) perform fitting operations on the plurality of fit coefficients and the plurality of gradient variable to determine superpositions for the plurality of fit coefficients; e) transmit the superpositions for the plurality of fit coefficients to a controller of the device; f) retrieve operating parameters of the device; g) determine one or more attributes that are not directly measured; h) determine values for the one or more attributes based on the superpositions of the plurality of fit coefficients; and i) control the device to perform the process.

### CROSS REFERENCE TO RELATED APPLICATIONS

This application claims the benefit of and priority to U.S. Provisional Application No. 63/675,534, filed Jul. 25, 2024, which application is hereby incorporated by reference in its entirety.

### FIELD

The field of the disclosure relates to ingot pullers for growing single crystal silicon ingots and, more particularly, to systems and methods for controlling the single crystal silicon ingot growth process using model based lumped parameter estimation of axial gradients at the melt-crystal interface.

### BACKGROUND

Single crystal silicon, which is the starting material for most processes for the fabrication of many electronic components such as semiconductor devices and solar cells, is commonly prepared by Czochralski (CZ) growth methods. In these methods, a polycrystalline source material, such as polycrystalline silicon (“polysilicon”), in the form of solid feedstock material is charged to a quartz crucible and melted, a single seed crystal is brought into contact with the molten silicon or melt, and a single crystal silicon ingot is grown by slow extraction.

Ingot pulling apparatus, or ingot pullers, include a hot zone that contributes to melting the polycrystalline silicon, as well as controlling dynamics of the melt, melt-crystal interface, and ingot growth (e.g., solidification or cooling). The hot zone typically includes heaters and several other hot zone components (e.g., insulation, cooling jackets) that facilitate controlling temperature within a growth chamber of the ingot puller, as well as other components of the ingot puller (e.g., susceptor) that are in proximity to the heater.

The thermal gradients are the essential parameters describing the dynamic behavior in crystal growth systems. Knowing the gradients enables one to tune growth processes with respect to point defect content, cooling conditions, etc. Unfortunately, thermal gradients cannot be measured in-run. Thus, they must be estimated from measurable variables by means of a model.

There exists a need for systems and methods for controlling ingot pullers using a model that facilitates enhanced and precise thermal gradient measurement and doing so in-run.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one aspect, a system for lumped parameter estimation includes a) a computer device comprising at least one processor in communication with at least one memory device; b) a controller for controlling a process performed by a device; and c) one or more sensors for monitoring the process, where the one or more sensors are in communication with the controller. The at least one processor may be configured to: 1) receive data for simulating the process on the device; 2) determine a plurality of gradient variables based on the data for simulating the process on the device; 3) determine a plurality of fit coefficients for the plurality of gradient variables; 4) perform fitting operations on the plurality of fit coefficients and the plurality of gradient variable to determine superpositions for the plurality of fit coefficients; and 5) transmit the superpositions for the plurality of fit coefficients to the controller. The controller is programmed to: i) retrieve operating parameters of the device; ii) determine one or more attributes that are not directly measured; iii) determine values for the one or more attributes based on the superpositions of the plurality of fit coefficients; and iv) control the device to perform the process based on the values for the one or more attributes. The system may have additional, less, or alternate functionalities, including those discussed elsewhere herein.

In another aspect, a computer-implemented method may be performed by a computer device including at least one processor in communication with at least one memory device. The method may include a) receiving data for simulating a process on the device; b) determining a plurality of gradient variables based on the data for simulating the process on the device; c) determining a plurality of fit coefficients for the plurality of gradient variables; d) performing fitting operations on the plurality of fit coefficients and the plurality of gradient variable to determine superpositions for the plurality of fit coefficients; e) transmitting the superpositions for the plurality of fit coefficients to a controller of the device; f) retrieving, by the controller of the device, operating parameters of the device; g) determining, by the controller of the device, one or more attributes that are not directly measured; h) determining, by the controller of the device, values for the one or more attributes based on the superpositions of the plurality of fit coefficients; and i) controlling, by the controller, the device to perform the process based on the values for the one or more attributes. The method may have additional, less, or alternate functionalities, including those discussed elsewhere herein.

Advantages will become more apparent to those skilled in the art from the following description of the preferred embodiments which have been shown and described by way of illustration. As will be realized, the present embodiments may be capable of other and different embodiments, and their details are capable of modification in various respects. Accordingly, the drawings and description are to be regarded as illustrative in nature and not as restrictive.

### BRIEF DESCRIPTION OF THE DRAWINGS

The Figures described below depict various aspects of the systems and methods disclosed. Each Figure depicts an embodiment of a particular aspect of the disclosed systems and methods, and that each of the Figures is intended to accord with a possible embodiment. Further, wherever possible, the following description refers to the reference numerals included in the following Figures, in which features depicted in multiple Figures are designated with consistent reference numerals.

FIG. 1 illustrates an ingot pulling apparatus (also known as an ingot puller) in accordance with at least one embodiment.

FIGS. 2A and 2B illustrate processes for model based lumped parameter estimation of axial gradients in melt and crystal at the growing interface.

FIG. 3 is a simplified block diagram of an example system for model based lumped parameter estimation of axial gradients in melt and crystal at the growing interface using the process shown in FIG. 2 with the ingot pulling apparatus shown in FIG. 1.

FIG. 4 depicts an example configuration of user computer device.

Like reference symbols in the various drawings indicate like elements.

### DETAILED DESCRIPTION

The field of the disclosure relates to ingot pullers for growing single crystal silicon ingots and, more particularly, to systems and methods for controlling the single crystal silicon ingot growth process using model based lumped parameter estimation of axial gradients at the melt-crystal interface.

Ingot pullers used to grow silicon ingots by the CZ methods use a batch system, i.e., it undergoes a permanent operating point (OP) change. The OP change is expressed in terms of heater power change during growth and depends on several factors. Primary ones include i) crystal radius, ii) growth rate, iii) crystal mass and iv) numerous terms describing the interaction of the growing crystal with inner assemblies of the puller hot zone. The ingot puller needs to be controlled to compensate for the OP change.

The embodiments described herein relate to ingot pulling apparatus, or ingot pullers, used to grow single crystal semiconductor ingots by a CZ growth process. The ingot pullers according to this disclosure include a controller that implements model based lump parameter estimation of axial gradients in melt and crystal at the growing interface. The estimation of the present disclosure can be applied in-run similar to the thermal heater power feedforward control. The aspects of the present disclosure can advantageously be utilized in model-based or model predictive control (gradient implementation to the MPC), as well as conventional process development and control. Furthermore, the systems and methods described herein provide for a model for the estimation of gradients in melt and crystal at the growing interface. This model is based on a thermal model. The model includes lumped parameters and can be implemented on a programmable logic controller (PLC).

In some embodiments, the systems and methods of the present disclosure can be used for growth of so-called Perfect Silicon (PS) (or Neutral Silicon) quality single crystal silicon ingots. Those having ordinary skill in the art would understand that although the present systems and methods are described in view of single silicon ingots, the present systems and methods may also be applied to types of materials for analysis.

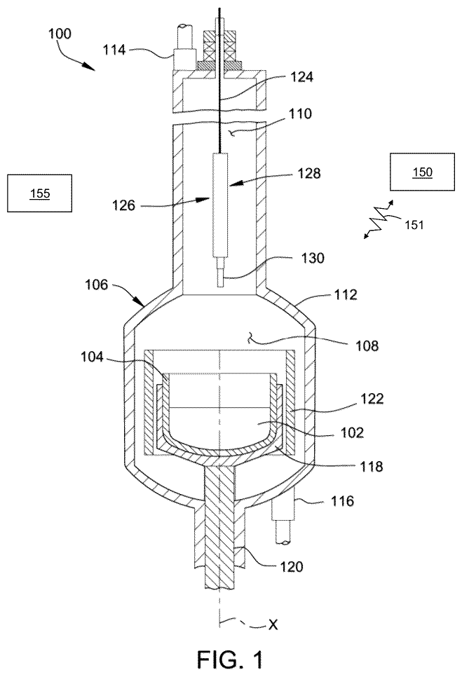

FIG. 1 illustrates an ingot pulling apparatus 100 (also known as an ingot puller 100) in accordance with at least one embodiment. The ingot puller 100 is used to produce single crystal (i.e., monocrystalline) ingots of semiconductor or solar-grade material such as, for example, single crystal silicon ingots. In some embodiments, the ingot is grown by the so-called Czochralski (CZ) process in which the ingot is withdrawn from a silicon melt 102 held within a crucible 104 of crystal puller 100. In some embodiments, the ingot is grown by a batch CZ process in which polycrystalline silicon is charged to the crucible 104 in an amount sufficient to grow one ingot, such that the crucible 104 is essentially depleted of silicon melt 102 after the growth of the one ingot. Embodiments of the subject matter described herein are not limited to a particular crystal growth process, however. For example, in other embodiments, a polycrystalline silicon ingot may be grown using a directional solidification process for solar applications.

The ingot puller 100 includes a housing 106 that defines a crystal growth chamber 108 and a pull chamber 110 having a smaller transverse dimension than the growth chamber 108. The growth chamber 108 has a generally dome shaped upper wall 112 transitioning from the growth chamber 108 to the narrowed pull chamber 110. The ingot puller 100 includes an inlet port 114 and an outlet port 116 which may be used to introduce and remove a process gas to and from the ingot puller 100 during crystal growth.

The crucible 104 within the ingot puller 100 contains the silicon melt 102 from which a silicon ingot is drawn. The crucible 104 may be made of quartz or fused silica, which has a high melting point and thermal stability and is generally non-reactive with molten silicon in melt 102. It should be understood that the crucible 104 may be made from other materials in addition to quartz without departing from the scope of the present disclosure. For example, the quartz crucible 104 may be made from a composite material that includes silica and an additional material, for example, silicon nitride or silicon carbide.

The silicon melt 102 is obtained by melting polycrystalline silicon charged to the crucible 104. In continuous systems, a feed system (not shown) is used for feeding solid feedstock material into the crucible assembly 104 and/or the melt 102. The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100. Susceptor 118 and crucible 104 are also vertically moveable in some embodiments. Rotational and vertical movement of the susceptor 118 and crucible 104 may be controlled throughout the ingot growth process by a controller 150 of the ingot puller 100.

A heating system 122 (e.g., one or more an electrical resistance heaters) surrounds the susceptor 118 and crucible 104 and supplies heat by conduction through the susceptor 118 and crucible 104 for melting the silicon charge to produce the melt 102 and/or maintaining the melt 102 in a molten state. The heating system 122, or heater 122, can include a bottom heater below the crucible 104 and a side heater laterally adjacent the crucible 104. Additionally or alternatively, the heater 122 extends from the side to below the susceptor 118 and crucible 104.

The heating system 122 is controlled by the controller 150 so that the temperature of the melt 102 is precisely controlled throughout the pulling process. For example, the controller 150 may control electric current provided to the heating system 122 to control the amount of thermal energy supplied by the heating system 122. The controller 150 may control the heating system 122 so that the temperature of the melt 102 is maintained above about the melting temperature of silicon (e.g., about 1412° C.). For example, the melt 102 may be heated to a temperature of at least about 1425° C., at least about 1450° C. or even at least about 1500° C. Insulation (not shown) surrounding the heating system 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

A pulling mechanism (not shown) is attached to a pull wire 124 that extends down from the mechanism. The mechanism is capable of raising and lowering the pull wire 124 and rotating the pull wire 124. The ingot puller 100 may have a pull shaft rather than a wire, depending upon the type of puller. The pull wire 124 terminates in a pulling assembly 126 that includes a seed crystal chuck 128 which holds a seed crystal 130 used to grow the silicon ingot. In growing the ingot, the pulling mechanism lowers the seed crystal 130 until it contacts the surface of the silicon melt 102. Once the seed crystal 130 begins to melt, the pulling mechanism slowly raises the seed crystal up through the growth chamber 108 and pull chamber 110 to grow the single crystal ingot. The speed at which the pulling mechanism rotates the seed crystal 130 and the speed at which the pulling mechanism raises the seed crystal (i.e., the pull rate v) are controlled by the controller 150. As the seed crystal 130 is slowly raised from the melt 102, silicon atoms from the melt 102 align themselves with and attach to the seed crystal 130 to form an ingot at the interface.

A process gas (e.g., argon) is introduced through the inlet port 114 into the growth chamber 108 and pull chamber 110 and is withdrawn through the outlet port 116. The process gas creates an atmosphere within the housing and the melt and atmosphere form a melt-gas interface. The outlet port 116 is in fluid communication with an exhaust system (not shown) of the ingot puller.

The ingot puller 100 also includes the controller 150 communicatively connected to various components of the puller 100, including the heater 122, the pulling mechanism, a susceptor/crucible rotatable drive unit, a susceptor/crucible lift unit, as well as other auxiliary components of the puller 100 such as temperature sensors (e.g., pyrometers), optical units (e.g., infrared (IR) cameras), a cooling jacket, among others. Although a single controller 150 is shown and described, the controller 150 may include multiple controllers 150 that may be centralized or decentralized. The controller 150 controls various aspects and parameters of the ingot puller 100 during the ingot growth process 100. For example, the controller 150 controls electric current supplied to the heater 122 to control the amount of thermal energy supplied by the heater 122. The controller 150 also controls operation of the pulling mechanism and the movement of the crucible 104. For example, the controller 150 may control a pull rate of the pull wire 124, a rotation rate of the seed crystal 130, a rotation rate of the crucible 104, a vertical position of the crucible 104 in the growth chamber 108, and/or using the gradient and fit model described herein to control the heater 122 and/or monitor conditions in real-time.

The controller 150 may receive feedback and monitored process information from one or more sensors 155, such as pyrometers, IR cameras, or another suitable sensor type, for continuous, periodic, or intermittent monitoring of conditions within the growth chamber 108, such as the temperature of the melt 102, temperature at the solid-melt interface between the melt 102 and a growing crystal, a surface level of the melt 102 (i.e., a vertical position of the melt surface), the temperature of the growing crystal, among other information. The sensors 155 may be communicatively connected with controller 150 to provide feedback information about the ingot growth process to the controller 150.

The controller 150 may include a communication interface to communicatively couple the controller 150, via one or more connections 151, to one or more components of the ingot puller 100. For example, the one or more connections 151 may communicatively couple the controller 150 to the heater 122, the pulling mechanism, the crucible drive unit, the crucible lift unit, sensors 155 (e.g., pyrometers and IR cameras), the cooling jacket, and/or other components of the ingot puller 100. The communication interface may include, for example, a wired or wireless network adapter and/or a wireless data transceiver for use with a mobile telecommunications network. In this way, the one or more connections 151 may communicatively couple the controller 150 to the one or more components of the ingot puller 100 via a wired and/or wireless connection.

Ingot pullers, e.g., the ingot puller 100, used for the CZ crystal growth process are a batch system, i.e., they undergo a permanent operating point (OP) change. The OP change is expressed in terms of heater power change (e.g., power change of the heater 122) during growth and depends on several factors. The main ones are i) crystal radius, ii) growth rate, iii) crystal mass, iv) melt mass, and v) numerous terms describing the interaction of the growing crystal with inner assemblies of the puller hot zone. Compensation of the OP change is also referred to as “feedforward control.”

Systems and methods for compensating for the operating point (OP) change in CZ crystal growth processes by means of a “feedforward control.” In at least one embodiment, feedforward control describes lumped parameters model implemented to control CZ crystal growth processes and determining a set of suitable model terms describing the OP change as precise as possible in industry scale ingot pullers. The principle also describes using a lumped model to describe the OP change in Cz systems.

In this disclosure, the lumped parameter model for feedforward control is applied to model the thermal gradients of a crystal growth process that describe the dynamic behavior in crystal growth systems, which allows tuning the growth processes with respect to point defect content, etc. Advantageously, it can be applied in-run similar to the thermal heater power feedforward control. Additionally, as described further below, the model based lumped parameter estimation of axial gradients at the melt-crystal interface according to the present disclosure can be leveraged for growth of Perfect Silicon quality ingots, described below.

Gradients determine the flux of heat through the growing interface and are, therefore, indicators of the thermal state of the Cz system. If the thermal properties of the system change, the gradients change as well and vice versa. Thus, the gradient model is coupled to a thermal model of Cz in a qualitative and quantitative manner. This accounts for why the majority of thermal model terms occur in slightly modified form in the gradient model as well.

Since gradients cannot be measured directly, available measurements need to be used in an appropriate model as a workaround to draw conclusions about the thermal state of the system and thus gradients. Such measurements include heater power \dot{Q}, positions, rates, etc. Because of the aimed in-run applicability the required model is a lumped one. The main available measurement containing information about the thermal state of the system, is heater power \dot{Q}. This disclosure describes how to derive gradients at the growing interface from heater power.

For the purposes of discussion of the model(s), the following terms have their corresponding definitions as described herein. ρₘ and ρₛ—mass densities of melt and crystal; r—crystal radius; r_{c}—crucible radius; λₘ and λₛ—thermal conductivities of melt and crystal; ξ₁-coefficient of model 1; ξ(n)—coefficient of model term n; Gₘ and Gₛ—thermal gradients at interface; ΔH_{f}—heat of fusion; v_{g}—growth rate; α—crystal slope angle; mₘ—melt mass; ϵ and σ—thermal emissivity and Stefan-Boltzmann constant; T(l)—T distribution along the crystal jacket; and HR—HR (height of reflector) gap between melt and reflector. The distance between the surface of the melt 102 and the lower reflector edge is also known as the ‘HR gap.’

The growth system is mainly determined by the flux of heat \dot{Q} through the growing interface being directly connected to the thermal gradient Gₛ.

$$\dot{Q} = A {λ}_{s} {G}_{s} \qquad EQ . 1$$

where Gₛ becomes

$${G}_{s} = \frac{\dot{Q}}{A {λ}_{s}} \qquad EQ . 2$$

A denotes the crystal cross section. This can be stated as πr² for cylindrical geometry. The flux through the interface consists of two components 1) oncoming heat flux through melt and 2) release of latent heat at the interface as a source term.

$$\dot{Q} = π {r}^{2} ( {λ}_{m} {G}_{m} + {ρ}_{s} Δ {H}_{f} {v}_{g} ) \qquad EQ . 3$$

Combining EQ. 1 and EQ. 3 provides the heat-flux balance at the growing interface.

$${λ}_{s} {G}_{s} = {λ}_{m} {G}_{m} + {ρ}_{s} Δ {H}_{f} {v}_{g} \qquad EQ . 4$$

EQ. 4 and 5 define the correlation between Gₛ and Gₘ:

$${G}_{m} = \frac{{λ}_{s} {G}_{s} - {ρ}_{s} Δ {H}_{f} {v}_{g}}{{λ}_{m}} \qquad EQ . 5$$

The gradient in crystal, Gₛ, is used in the thermal model. This way, both models are firmly coupled to each other. Since experimental Gₛ is not known in the beginning, thermal and gradient model equations can only be solved jointly and iterative. The iteration is done until Gₛ reaches a pre-defined target. Similarly, v/G may be used as iteration target, e.g., for PS runs.

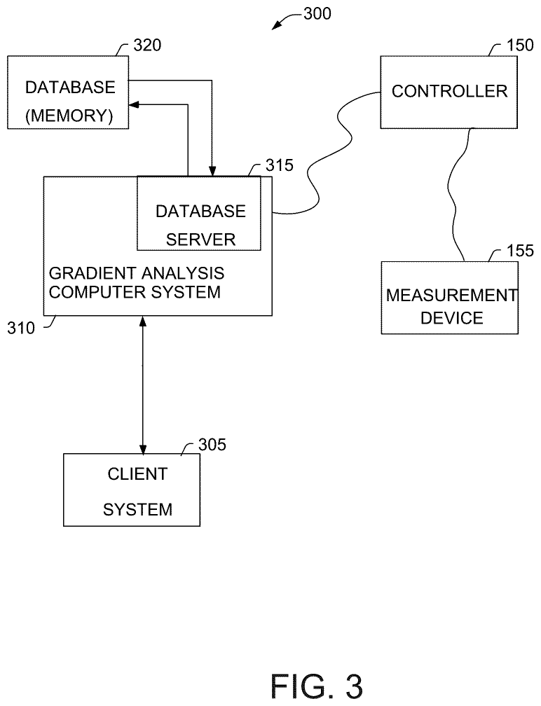

The iteration is, certainly, only necessary for the gradient estimation form experimental data. This iteration fitting is performed by the GA server 310 (shown in FIG. 3). The results of the iteration fitting are then provided to the controller 150. This allows the controller 150 to quickly and efficiently calculate the recipe data in-run as target values. In this case, the controller 150 only needs to solve some single algebraic equations. Since, this does not require huge computational efforts and thus, the model can easily be integrated into a programmable logic controller (PLC), such as controller 150, to be performed in real-time or near real-time.

The gradient Gₛ consists of various impact factors. These can roughly be categorized by conductive, radiative and conductive/radiative transport of heat inside the system. The current model approach is proposed as a superposition of a set of such single contributions:

$${G}_{s} = {G}_{{s}_{r}} + {G}_{{s}_{lat}} - {G}_{ad} + {G}_{ct} + {G}_{{s}_{plug}} + {G}_{{s}_{ia}} + {G}_{{s}_{HR}} \qquad EQ . 6$$

The first term is the radius dependency of Gₛ. This is a consequence of conduction/radiation in the Cz system. One solution for the temperature profile along the crystal jacket when a crystal cylinder is in direct contact with the melt 102. Gₛ_{ᵣ} at the growing interface is derived there to be:

$${G}_{{s}_{r}} = {κ ( \frac{2 ϵ σ {T}^{5}}{3 {λ}_{s} r} )}^{\frac{1}{2}} \qquad EQ . 7$$

EQ. 7 defines the radius dependency of the axial gradient in the crystal scales with about \sqrt{r⁻¹}. The coefficient κ is used within the iteration procedure to achieve the requested absolute gradient value.

When looking at EQ. 4, the conductive heat balance at the interface, the contribution of latent heat to Gₛ can be derived. It becomes:

$${G}_{{s}_{lat}} = \frac{{ξ}_{1} {ρ}_{s} Δ {H}_{f} {v}_{g}}{{λ}_{s}} \qquad EQ . 8$$

This equals thermal model term 3 EQ. 8, normalized by crystal cross section and thermal conductivity. Here, ξ₁ denotes the fit coefficient of the thermal model for the latent heat term.

Advection reduces the gradient and thus, shows a negative sign.

$${G}_{{s}_{ad}} = - \frac{{ξ}_{2} 2 {ρ}_{s} {c}_{{p}_{s}} {T}_{m} {v}_{g}}{7 {λ}_{s}} \qquad EQ . 9$$

This leads to terms which are more bound to radiative transfer of heat inside the hot zone. They may be understood therefore similarly like view factors. These model terms cannot be normalized to a specific cross section as done for the conductive terms before. Moreover, only the quantitative normalization to λₛ remains. All of the following gradient contributions are treated likewise. The n in EQs. 8-13 stands for the successive numbering of all model terms which matches the number of the ξ-vector components listed in those equations.

The radiative interaction between heater and the conical parts of the crystal (crown/tail) are described in EQ. 10. It is used twice, once for crown and once for the tail. The ξ-vector includes multiple numbers based on the number of terms in the equation. For G_{ct}, there are two terms in the equation, one for the crown and one for the tail, accordingly, there are two fit coefficients ξ₃ and ξ₄.

$${G}_{ct} = \frac{{ξ}_{3 , 4}}{{λ}_{s}} sin ( α ) ( {r}_{c}^{2} - {r}^{2} ) . \qquad EQ . 10$$

When the crystal grows into the reflector, the view between the hot, radiating, melt surface and upper hot-zone assemblies becomes blocked or “plugged” and un-plugged later in tail. There are four terms in EQ. 11, one for plugging and three for unplugging. Accordingly, there are four fit coefficients ξ₅-ξ₈. The n represents the term corresponding to the fit coefficient (5-8). Plugging and un-plugging components of the gradient result and follow the general expression:

$${G}_{{s}_{plug}} = \frac{{ξ}_{5 - 8}}{{λ}_{s}} ( {{r}_{shift} ( n )}^{2} - {r}_{i}^{2} ) \qquad EQ . 11$$

The next terms describe the direct radiative interaction between crystal and inner hot-zone assemblies. Since there are seven terms, there are seven fit coefficients (ξ₉-ξ₁₅) and n corresponds to the number of the fit coefficient.

$${G}_{{s}_{ia}} = \frac{{ξ}_{9 - 15}}{{λ}_{s}} ∈ σ π {{r}_{shift} ( n )}^{2} {T ( n )}^{4} \qquad EQ . 12$$

Similarly, the HR gap effect reads:

$${G}_{{s}_{HR}} = \frac{{ξ}_{16}}{{λ}_{s} HR} \qquad EQ . 13$$

In the example embodiment, the controller 150 or other computer device are able to determine and/or measure some of these variables. However, the controller 150 generally has limited processing power and is not set-up to perform the processing for performing iterative fitting. Accordingly, it is more efficient for the GA server 310 to iteratively solve for all of the fit coefficients. In some embodiments, the GA server 310 solves for as many of these gradient equations (EQ. 7-EQ. 13) as possible. Then the equations are applied to EQ. 6. The solved for fit coefficients are transmitted to the controller 150 to allow it to drive the ingot making process. In other embodiments, the controller 150 solves for the gradient equations (EQ. 7-EQ. 13). Then the controller 150 applies the equations to EQ. 6.

Then the controller 150 receives/determines/measures some of the variables, such readings from one or more sensors 155 and one or more settings of the system 100. The controller 150 usings the fit coefficients, real-time variables, and settings to solve EQ. 6 for Gₛ and may then use Gₛ in EQ. 1 and other equations as needed. More specifically, by determining these different attributes, the controller 150 may use them to adjust different parameters of the system 100 as needed to improve the quality of the output of the Cz crystal growth. Accordingly, by performing the fitting on the GA server 310, this reduces the required load on the controller 150 in real-time during the ingot making process. Thereby increasing the speed and accuracy of monitoring and adjusting for the process.

The model provides the estimation of unmeasurable real thermal gradients at the growing interface. This gives access to the real dynamic properties of Cz systems. This approach proposes the superposition of different gradient parts which directly rely on the thermal model.

Because of its simplicity, the invention provides in-run capability (implementation into PLC) and can easily be quantified because it is based on the thermal lumped parameter model. Knowledge of Cz system dynamics can be exploited in estimation of cooling conditions of the crystal, and defect type for PS crystals.

Knowing the axial gradients, especially those in the crystal enables the controller 150 to estimate: 1) v/G (which can be leveraged to grow Perfect Silicon); 2) growth rate trajectory planning according to an aimed v/G; 3) cooling rates v*G; and 4) general dynamical behavior of growth processes.
For 1), when Gₛ is known, the controller 150 can calculate the average v_{g}/Gₛ (or simply v/G) trajectory during run.
For 2), the inverse application to this is to calculate the target growth rate v_{g} trajectory by means of a targeted v_{g}/Gₛ.
For 3), calculation of v_{g}*Gₛ delivers the cooling rates at interface.

While the above describes the system 100 and equations in view of heater power, one having ordinary skill in the art would understand that the above system 100 and equations may also be calculated in view of heater temperature instead of power.

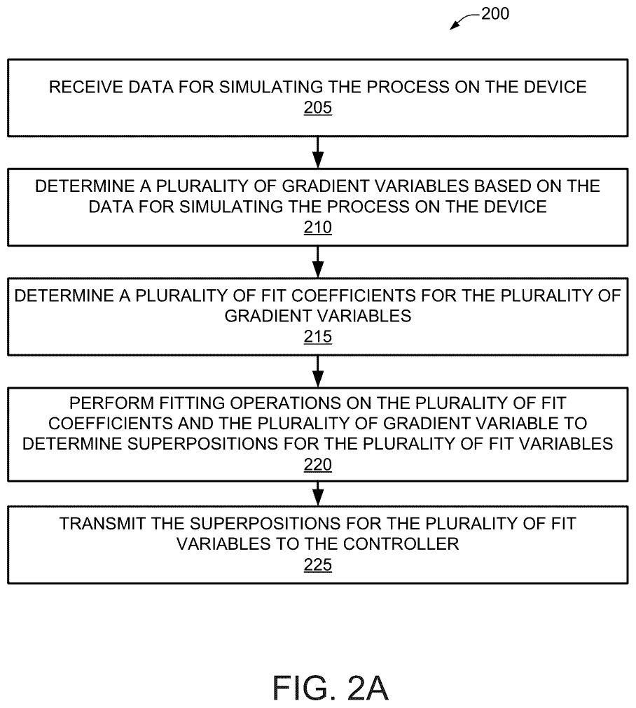

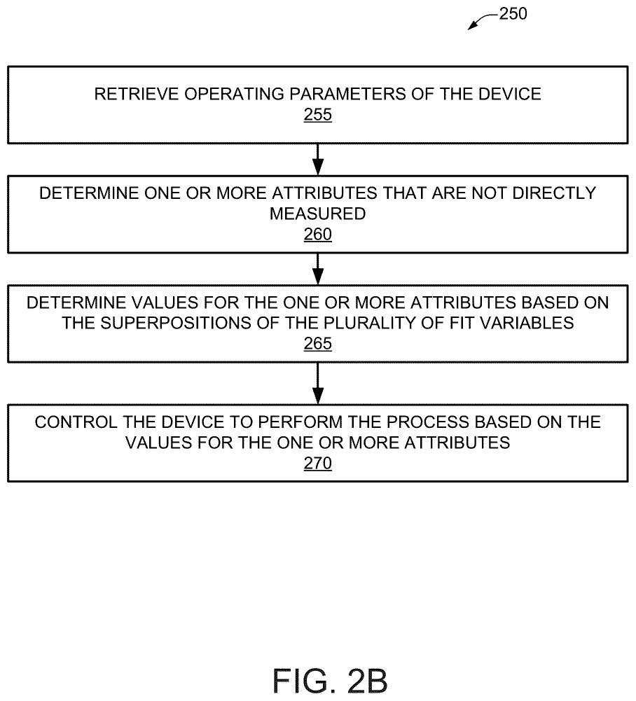

FIGS. 2A and 2B illustrate processes 200 and 250 for model based lumped parameter estimation of axial gradients in melt and crystal at the growing interface. In the example embodiment, the steps of process 200 are performed by the GA server 310 (shown in FIG. 3). In the example embodiment, the steps of process 250 are performed by the controller 150 (shown in FIG. 1). In some embodiments, the controller 150 is a programmable logic controller (PLC). In some embodiments, the controller 150 and GA server 310 perform model based lumped parameter estimation of axial gradients in melt and crystal at the growing interface.

In the example embodiment, the GA server 310 receives 205 data for simulating the process on the device. In some embodiments, the data for simulating the process is experimental data. In other embodiments, the data for simulating the process is historical data. In some embodiments, the data is received 205 from one or more client systems 305 (shown in FIG. 3). In the example embodiment, the process is growing an ingot. In some embodiments, the ingot is a single crystal silicon ingot. In some further embodiments, the device is an ingot pulling apparatus 100 (shown in FIG. 1).

In some embodiments, the data for simulating the process includes operating parameters for the device 100 during the simulation. In some embodiments, the operating parameters are provided by the controller 150. In other embodiments, the operating parameters are provided by the user, such as via the client system 305. In additional embodiments, the data for simulating the process includes data that was measured by the sensor data of the process being performed by the device 100. The sensor data may be received from one or more sensors 155 (shown in FIG. 1). In some embodiments, the sensor data was received in real-time by the sensors 155 and transmitted to the GA server 310.

In the example embodiment, the GA server 310 determines 210 a plurality of gradient variables based on the data for simulating the process on the device 100. The gradient variables may include those described in EQ. 6-13. In some embodiments, the plurality of gradient variables includes at least one of conductive heat balance at an interface, advective flux, radius conduction/radiation, radiative interaction between a heater, a crown, a tail, plugging and un-plugging components, direct radiative interaction, and a heat reflector gap.

In the example embodiment, the GA server 310 determines 215 a plurality of fit coefficients for the plurality of gradient variables. In some embodiments, the GA server 310 determines 215 fit coefficients for each term in the equations for the plurality of gradient variables.

In the example embodiment, the GA server 310 performs 220 fitting operations on the plurality of fit coefficients and the plurality of gradient variable to determine superpositions for the plurality of fit coefficients. In some embodiments, the GA server 310 determines superpositions for the plurality of fit coefficients by iteratively performing a least squares fit algorithm. In other embodiments, the GA server 310 uses other fitting algorithms to determine the superpositions. In some embodiments, the GA server 310 stops the iterative fitting when an error is below a threshold. In other embodiments, the GA server 310 stops the iterative fitting when an amount of change between iterations is below a change threshold.

In some embodiments, the GA server 310 performs the iterative fitting three times with three different sets of data and then determines the fitting coefficients from the three solutions. In some further embodiments, the GA server 310 takes the average of the three fittings. In some embodiments, other numbers of fittings may be used and combined in other manners.

In the example embodiment, the GA server 310 transmits 225 the superpositions for the plurality of fit coefficients to the controller 150.

In the example embodiment, the controller 150 retrieves 255 operating parameters of the device 100. The operating parameters include details that are set on the device 100. This may include, but is not limited to, heater temperature, pulling speed, heater power, and/or one or more known attributes of the ingot.

In the example embodiment, the controller 150 determines 260 one or more attributes that are not directly measured. These are attributes that may be changing as conditions change and/or interior to the ingot and therefore not able to be directly measured and/or know.

In the example embodiment, the controller 150 determines 265 values for the one or more attributes based on the superpositions of the plurality of fit coefficients. In the example embodiment, the controller 150 reads the fit coefficients from GA server 310 and calculates the i) real (experimental) gradient as well as the ii) target gradient. For i) it needs measured data, fit coefficients, and operating data. For ii) all data come from GA server 310.

In the example embodiment, the controller 150 controls 270 the device to perform the process based on the values for the one or more attributes.

In some further embodiments, the controller 150 receives sensor data of the process being performed by the device. The sensor data may be received from one or more sensors 155 (shown in FIG. 1). The controller 150 determines adjusted values for the one or more attributes based on the superpositions of the plurality of fit coefficients and the sensor data. The controller 150 adjust one or more operating parameters of the device based on the adjusted values for the one or more attributes.

In further embodiments, the GA server 310 transmits one or more of the plurality of gradient variables to the controller 150.

In some further embodiments, the controller 150 generates a series of steps to perform the process and corresponding operating parameters for those series of steps based on the values for the one or more attributes and the superpositions of the plurality of fit coefficients. In some embodiments, this series of steps and operating parameters is called a ‘recipe.’ In some of these embodiments, the controller 150 generates different recipes for different desired radii of ingots, pull speeds, etc.

In some further embodiments, the controller 150 adjusts the ingot puller device 100 by changing a temperature of a heater 122 (shown in FIG. 1). In additional embodiments, the controller 150 adjusts the ingot puller device 100 by changing a pulling speed. In further embodiments, the controller 150 performs the adjustment at a subsequent time and/or after a delay.

In the example embodiment, by performing the iterative fitting processing on the GA server 310, this moves the heavy processing to be performed offline. By providing the results of the fittings to the controller 150, this simplifies the processing that the controller 150 needs to perform and therefore reduces the computer resources that are needed to be used by the controller 150. This allows the controller 150 to more quickly monitor and adjust the process of ingot creation in real-time.

FIG. 3 is a simplified block diagram of an example system 300 for model based lumped parameter estimation of axial gradients in melt and crystal at the growing interface using the process 200 (shown in FIG. 2) with the ingot pulling apparatus 100 (shown in FIG. 1). In the example embodiment, system 300 is used for analyzing ingots. In addition, system 300 a gradient analysis (GA) computer device 310 (also known as a GA server) configured to analyze ingots and determine model based lumped parameter estimation of axial gradients in melt and crystal at the growing interface.

As noted above, one or more measurement devices or sensors 155 are configured to measure one or more attributes of the system 100. The one or more measurement devices 155, may include, but are not limited to, pyrometers, IR cameras, or another suitable sensor type, for continuous, periodic, or intermittent monitoring of conditions within the growth chamber 108, such as the temperature of the melt 102, temperature at the solid-melt interface between the melt 102 and a growing crystal, a surface level of the melt 102 (i.e., a vertical position of the melt surface), the temperature of the growing crystal, among other information (all shown in FIG. 1). The one or more measurement devices 155 may be communicatively connected with controller 150 to provide feedback information about the ingot growth process to the controller 150. The measurement devices 155 connects to the GA computer device 310 through the controller 150 through various wired or wireless interfaces including without limitation a network, such as a local area network (LAN) or a wide area network (WAN), dial-in-connections, cable modems, Internet connection, wireless, and special high-speed Integrated Services Digital Network (ISDN) lines.

As described above in more detail, the GA server 310 is programmed to determine model based lumped parameter estimation of axial gradients in melt and crystal at the growing interface to program the controller 150 to respond to and prepare for changes that would cause the ingot to be out of tolerance quickly.

Client systems 305 are computers that include a web browser or a software application, which enables client systems 305 to communicate with the GA server 310 using the Internet, a local area network (LAN), or a wide area network (WAN). In some embodiments, client systems 305 are communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem. Client systems 305 can be any device capable of accessing a network, such as the Internet, including, but not limited to, a desktop computer, a laptop computer, a personal digital assistant (PDA), a cellular phone, a smartphone, a tablet, a phablet, or other web-based connectable equipment.

A database server 315 is communicatively coupled to a database 320 that stores data. In one embodiment, database 320 is a database that includes historical data and the equations. In some embodiments, database 320 is stored remotely from GA server 310. In some embodiments, database 320 is decentralized. In the example embodiment, a person can access database 320 via client systems 305 by logging onto GA server 310.

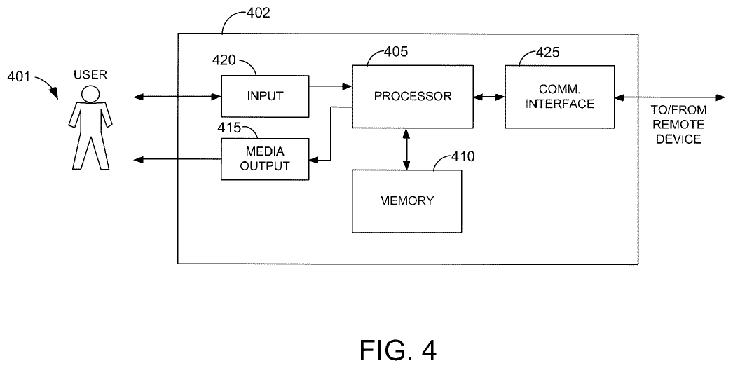

FIG. 4 depicts an example configuration 400 of user computer device 402. In the example embodiment, user computer device 402 may be similar to, or the same as, or include controller 150 (shown in FIG. 1), client systems 305, and GA server 310. User computer device 402 may be operated by a user 401.

User computer device 402 may include a processor 405 for executing instructions. In some embodiments, executable instructions may be stored in a memory area 410. Processor 405 may include one or more processing units (e.g., in a multi-core configuration). Memory area 410 may be any device allowing information such as executable instructions and/or transaction data to be stored and retrieved. Memory area 410 may include one or more computer readable media.

User computer device 402 may also include at least one media output component 415 for presenting information to user 401. Media output component 415 may be any component capable of conveying information to user 401. In some embodiments, media output component 415 may include an output adapter (not shown) such as a video adapter and/or an audio adapter. An output adapter may be operatively coupled to processor 405 and operatively couplable to an output device such as a display device (e.g., a cathode ray tube (CRT), liquid crystal display (LCD), light emitting diode (LED) display, or “electronic ink” display) or an audio output device (e.g., a speaker or headphones).

In some embodiments, media output component 415 may be configured to present a graphical user interface (e.g., a web browser and/or a client application) to user 401. A graphical user interface may include, for example, an interface for viewing items of information provided by the processor 308. In some embodiments, user computer device 402 may include an input device 420 for receiving input from user 401. User 401 may use input device 420 to, without limitation, submit information either through speech or typing.

Input device 420 may include, for example, a keyboard, a pointing device, a mouse, a stylus, a touch sensitive panel (e.g., a touch pad or a touch screen), a gyroscope, an accelerometer, a position detector, a biometric input device, and/or an audio input device. A single component such as a touch screen may function as both an output device of media output component 415 and input device 420.

User computer device 402 may also include a communication interface 425, communicatively coupled to a remote device such as controller 150. Communication interface 425 may include, for example, a wired or wireless network adapter and/or a wireless data transceiver for use with a mobile telecommunications network.

Stored in memory area 410 are, for example, computer readable instructions for providing a user interface to user 401 via media output component 415 and, optionally, receiving and processing input from input device 420. A user interface may include, among other possibilities, a web browser and/or a client application. Web browsers enable users, such as user 401, to display and interact with media and other information typically embedded on a web page or a website. A client application may allow user 401 to interact with, for example, controller 150. For example, instructions may be stored by a cloud service, and the output of the execution of the instructions sent to the media output component 415.

Processor 405 may execute computer-executable instructions for implementing aspects of the disclosure. In some embodiments, the processor 405 may be transformed into a special purpose microprocessor by executing computer-executable instructions or by otherwise being programmed. For example, the processor 405 may be programmed with the instruction such as illustrated in FIG. 2.

At least one of the technical problems addressed by this system may include: (i) improved control of ingot manufacturing; (ii) decreased loss of material due to malfunction; (iii) earlier determination of ingot quality; (iv) increased accuracy in ingot analysis; and/or (v) increased accuracy in ingot analysis.

### Additional Considerations

As will be appreciated based upon the foregoing specification, the above-described embodiments of the disclosure may be implemented using computer programming or engineering techniques including computer software, firmware, hardware or any combination or subset thereof. Any such resulting program, having computer-readable code means, may be embodied or provided within one or more computer-readable media, thereby making a computer program product, i.e., an article of manufacture, according to the discussed embodiments of the disclosure. The computer-readable media may be, for example, but is not limited to, a fixed (hard) drive, diskette, optical disk, magnetic tape, semiconductor memory such as read-only memory (ROM), and/or any transmitting/receiving medium such as the Internet or other communication network or link. The article of manufacture containing the computer code may be made and/or used by executing the code directly from one medium, by copying the code from one medium to another medium, or by transmitting the code over a network.

These computer programs (also known as programs, software, software applications, “apps,” or code) include machine instructions for a programmable processor and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, the terms “processor” and “computer” and related terms, e.g., “processing device”, “computing device”, and “controller” are not limited to just those integrated circuits referred to in the art as a computer, but broadly refers to a microcontroller, a microcomputer, a programmable logic controller (PLC), a reduced instruction set circuit (RISC), an application specific integrated circuit (ASIC), logic circuits, and any other circuit or processor capable of executing the functions described herein. The above examples are example only and are thus not intended to limit in any way the definition and/or meaning of the term “processor.”

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

As used herein, the term “database” can refer to either a body of data, a relational database management system (RDBMS), or to both. As used herein, a database can include any collection of data including hierarchical databases, relational databases, flat file databases, object-relational databases, object-oriented databases, and any other structured collection of records or data that is stored in a computer system. The above examples are example only, and thus are not intended to limit in any way the definition and/or meaning of the term database. Examples of RDBMS' include, but are not limited to including, Oracle® Database, MySQL, IBM® DB2, Microsoft® SQL Server, Sybase®, and PostgreSQL. However, any database can be used that enables the systems and methods described herein. (Oracle is a registered trademark of Oracle Corporation, Redwood Shores, California; IBM is a registered trademark of International Business Machines Corporation, Armonk, New York; Microsoft is a registered trademark of Microsoft Corporation, Redmond, Washington; and Sybase is a registered trademark of Sybase, Dublin, California.)

In another example, a computer program is provided, and the program is embodied on a computer-readable medium. In an example, the system is executed on a single computer system, without requiring a connection to a server computer. In a further example, the system is being run in a Windows® environment (Windows is a registered trademark of Microsoft Corporation, Redmond, Washington). In yet another example, the system is run on a mainframe environment and a UNIX® server environment (UNIX is a registered trademark of X/Open Company Limited located in Reading, Berkshire, United Kingdom). In a further example, the system is run on an iOS® environment (iOS is a registered trademark of Cisco Systems, Inc. located in San Jose, CA). In yet a further example, the system is run on a Mac OS® environment (Mac OS is a registered trademark of Apple Inc. located in Cupertino, CA). In still yet a further example, the system is run on Android® OS (Android is a registered trademark of Google, Inc. of Mountain View, CA). In another example, the system is run on Linux® OS (Linux is a registered trademark of Linus Torvalds of Boston, MA). The application is flexible and designed to run in various different environments without compromising any major functionality.

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

Furthermore, as used herein, the term “real-time” refers to at least one of the time of occurrence of the associated events, the time of measurement and collection of predetermined data, the time to process the data, and the time of a system response to the events and the environment. In the examples described herein, these activities and events occur substantially instantaneously.

In some embodiments, the system includes multiple components distributed among a plurality of computer devices. One or more components may be in the form of computer-executable instructions embodied in a computer-readable medium. The systems and processes are not limited to the specific embodiments described herein. In addition, components of each system and each process can be practiced independent and separate from other components and processes described herein. Each component and process can also be used in combination with other assembly packages and processes. The present embodiments may enhance the functionality and functioning of computers and/or computer systems.

The computer-implemented methods discussed herein can include additional, less, or alternate actions, including those discussed elsewhere herein. The methods can be implemented via one or more local or remote processors, transceivers, servers, and/or sensors (such as processors, transceivers, servers, and/or sensors mounted on vehicles or mobile devices, or associated with smart infrastructure or remote servers), and/or via computer-executable instructions stored on non-transitory computer-readable media or medium. Additionally, the computer systems discussed herein can include additional, less, or alternate functionality, including that discussed elsewhere herein.” The computer systems discussed herein can include or be implemented via computer-executable instructions stored on non-transitory computer-readable media or medium.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein can be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

The patent claims at the end of this document are not intended to be construed under 35 U.S.C. § 112 (f) unless traditional means-plus-function language is expressly recited, such as “means for” or “step for” language being expressly recited in the claim(s).

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A system for lumped parameter estimation, the system comprising:
a computer device comprising at least one processor in communication with at least one memory device;
a controller for controlling a process performed by a device; and
one or more sensors for monitoring the process, wherein the one or more sensors are in communication with the controller,
wherein the at least one processor is programmed to:
receive data for simulating the process on the device;
determine a plurality of gradient variables based on the data for simulating the process on the device;
determine a plurality of fit coefficients for the plurality of gradient variables;
perform fitting operations on the plurality of fit coefficients and the plurality of gradient variables to determine superpositions for the plurality of fit coefficients; and
transmit the superpositions for the plurality of fit coefficients to the controller,
wherein the controller is programmed to:
retrieve operating parameters of the device;
determine one or more attributes that are not directly measured;
determine values for the one or more attributes based on the superpositions of the plurality of fit coefficients; and
control the device to perform the process based on the values for the one or more attributes.

2. The system of claim 1, wherein the controller is further programmed to:
receive sensor data of the process being performed by the device;
determine adjusted values for the one or more attributes based on the superpositions of the plurality of fit coefficients and the sensor data; and
adjust one or more operating parameters of the device based on the adjusted values for the one or more attributes.

3. The system of claim 1, wherein the at least one processor is further programmed to transmit one or more of the plurality of gradient variables to the controller.

4. The system of claim 1, wherein the operating parameters include at least one of heater power, heater temperature, and pulling speed.

5. The system of claim 1, wherein the controller is further programmed to generate a series of steps to perform the process and corresponding operating parameters for those series of steps based on the values for the one or more attributes and the superpositions of the plurality of fit coefficients.

6. The system of claim 1, wherein the process is growing an ingot.

7. The system of claim 6, wherein the ingot is a single crystal silicon ingot.

8. The system of claim 1, wherein the device is an ingot pulling apparatus.

9. The computer device of claim 1, wherein the controller is a programmable logic controller (PLC) associated with the device.

10. The system of claim 1, wherein the at least one processor is further programmed to determine superpositions for the plurality of fit coefficients by iteratively performing a least squares fit algorithm.

11. The system of claim 10, wherein the at least one processor is further programmed to stop iterative fitting when at least one of:
i) an error is below a threshold; and
ii) a change between iterations is below a change threshold.

12. The system of claim 1, wherein the plurality of gradient variables includes at least one of conductive heat balance at an interface, advective flux, radius conduction/radiation, radiative interaction between a heater, a crown, a tail, plugging and un-plugging components, direct radiative interaction, and heat reflector gap.

13. A computer-implemented method for lumped parameter estimation, the computer-implemented method implemented by a computing device including at least one processor in communication with at least one memory device and a controller of a device, the method comprising:
receiving data for simulating a process on the device;
determining a plurality of gradient variables based on the data for simulating the process on the device;
determining a plurality of fit coefficients for the plurality of gradient variables;
performing fitting operations on the plurality of fit coefficients and the plurality of gradient variables to determine superpositions for the plurality of fit coefficients;
transmitting the superpositions for the plurality of fit coefficients to a controller of the device;
retrieving, by the controller of the device, operating parameters of the device;
determining, by the controller of the device, one or more attributes that are not directly measured;
determining, by the controller of the device, values for the one or more attributes based on the superpositions of the plurality of fit coefficients; and
controlling, by the controller, the device to perform the process based on the values for the one or more attributes.

14. The computer-implemented method of claim 13 further comprising:
receiving, by the controller, sensor data of the process being performed by the device;
determining, by the controller, adjusted values for the one or more attributes based on the superpositions of the plurality of fit coefficients and the sensor data; and
adjusting, by the controller, one or more operating parameters of the device based on the adjusted values for the one or more attributes.

15. The computer-implemented method of claim 13 further comprising transmitting one or more of the plurality of gradient variables to the controller.

16. The computer-implemented method of claim 13, wherein the operating parameters include at least one of heater power, heater temperature, and pulling speed.

17. The computer-implemented method of claim 13 further comprising generating, by the controller, a series of steps to perform the process and corresponding operating parameters for those series of steps based on the values for the one or more attributes and the superpositions of the plurality of fit coefficients.

18. The computer-implemented method of claim 13, wherein the process is growing an ingot, wherein the ingot is a single crystal silicon ingot, wherein the device is an ingot pulling apparatus, and wherein the controller is a programmable logic controller (PLC) associated with the device.

19. The computer-implemented method of claim 13 further comprising determining superpositions for the plurality of fit coefficients by iteratively performing a least squares fit algorithm.

20. The computer-implemented method of claim 19 further comprising stopping iterative fitting when at least one of:
i) an error is below a threshold; and
ii) a change between iterations is below a change threshold.
